(19) United States
(12) Patent Application Publication
(10) Pub. No.: US 2007/0063279 A1
(43) Pub. Date: Mar. 22, 2007

(54) Insulation layer for silicon-on-insulator wafer

(76) Inventors: Peter G. Tolchinsky, Beaverton, OR (US); Mohamad Shaheen, Portland, OR (US); Martin D. Giles, Portland, OR (US); Irwin Yablok, Portland, OR (US); Aaron A. Budrevich, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/231,002

(22) Filed: Sep. 16, 2005

(51) Int. Cl. H01L 27/12; H01L 27/01; H01L 31/0392; H01L 21/84; H01L 21/00

(52) U.S. Cl. 257/347; 438/149

(57) ABSTRACT

A method of forming a silicon-on-insulator wafer begins by providing a silicon wafer having a first surface. An ion implantation process is then used to implant oxygen within the silicon wafer to form an oxygen layer that is buried within the silicon wafer, thereby forming a silicon device layer that remains substantially free of oxygen between the oxygen layer and the first surface. An annealing process is then used to diffuse nitrogen into the silicon wafer, wherein the nitrogen diffuses into the silicon device layer and the oxygen layer. Finally, a second annealing process is used to form a silicon dioxide layer and a silicon oxynitride layer, wherein the second annealing process causes the implanted oxygen to react with the silicon to form the silicon dioxide layer and causes the diffused nitrogen to migrate and react with the silicon and the implanted oxygen to form the silicon oxynitride layer.

### BACKGROUND

In the manufacture of semiconductor wafers, silicon-on-insulator (SOI) technology can produce higher performing devices that often consume less power than devices built on conventional bulk silicon. An SOI wafer is typically formed by sandwiching an insulating layer, such as silicon oxide (SiO₂), between a thin layer of silicon and a bulk silicon substrate. The insulating layer is therefore “buried” within the silicon and may be referred to as a buried oxide (BOX) layer. FIG. 1 illustrates a conventional SOI wafer 100 with an insulating layer 102 formed between a thin layer of silicon 104 and a bulk silicon substrate 106. One or more integrated circuit devices, such as transistors, may be formed on the thin layer of silicon 104. The presence of the insulating layer 102 generally reduces capacitance, therefore the amount of electrical charge that each transistor has to move during a switching operation is generally reduced, making the transistor faster and allowing it to switch using less energy. In many instances, integrated circuits built on SOI wafers can be faster and use less power than conventional complementary metal-oxide semiconductor (CMOS) integrated circuits.

One conventional method of forming an SOI wafer is ion beam synthesis. For instance, oxygen and nitrogen can be implanted into a silicon wafer using an ion beam process. The wafer is then annealed to form a “separation by implantation of oxygen and nitrogen” wafer, known as a SIMON wafer. Similarly, the ion implantation process may only implant oxygen to form a SIMOX wafer (separation by implantation of oxygen) or only nitrogen to form a SIMNI wafer (separation by implantation of nitrogen).

After the BOX layer is formed, the SOI wafer undergoes processing to form devices such as transistors on the thin layer of silicon. This device processing may include etching processes. Unfortunately, conventional SOI wafers built with silicon dioxide as the insulating layer tend to have poor etch resistance. The device processing may therefore damage the BOX layer and adversely affect the performance of the resulting integrated circuit.

### BRIEF DESCRIPTION OF THE DRAWINGS

FIG. 1 illustrates a conventional SOI semiconductor wafer.

FIG. 2A illustrates an SOI wafer with a dual-insulation layer formed in accordance with an implementation of the invention.

FIG. 2B illustrates an SOI wafer with a tri-insulation layer formed in accordance with an implementation of the invention.

FIG. 3 is a process for forming an SOI wafer in accordance with an implementation of the invention.

FIGS. 4A and 4B illustrate initial steps of the process described in FIG. 3.

FIGS. 5A through 11 illustrate final steps of the process described in FIG. 3 for various implementations of the invention.

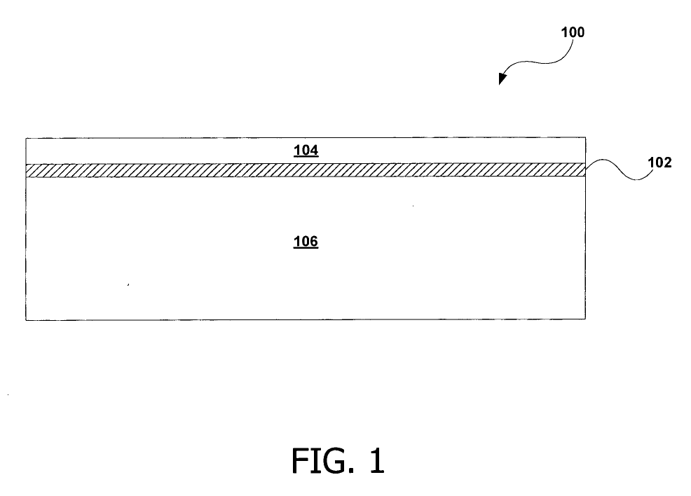

### DETAILED DESCRIPTION

Described herein are systems and methods of forming a silicon-on-insulator (SOI) semiconductor wafer with a multi-level insulating layer. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide an improved buried oxide (BOX) insulation layer for an SOI semiconductor wafer. In accordance with some implementations of the invention, the insulation layer includes a silicon oxynitride (SiON) layer and/or a nitrogen-doped silicon dioxide (N-doped SiO₂) layer. In some implementations, the insulation layer of the invention may include multiple layers where an undoped silicon dioxide (undoped-SiO₂) layer may be combined with one or both of the SiON layer and the N-doped SiO₂ layer. The insulation layer of the invention has improved etch resistance relative to conventional BOX layers when used in SOI wafers during device processing.

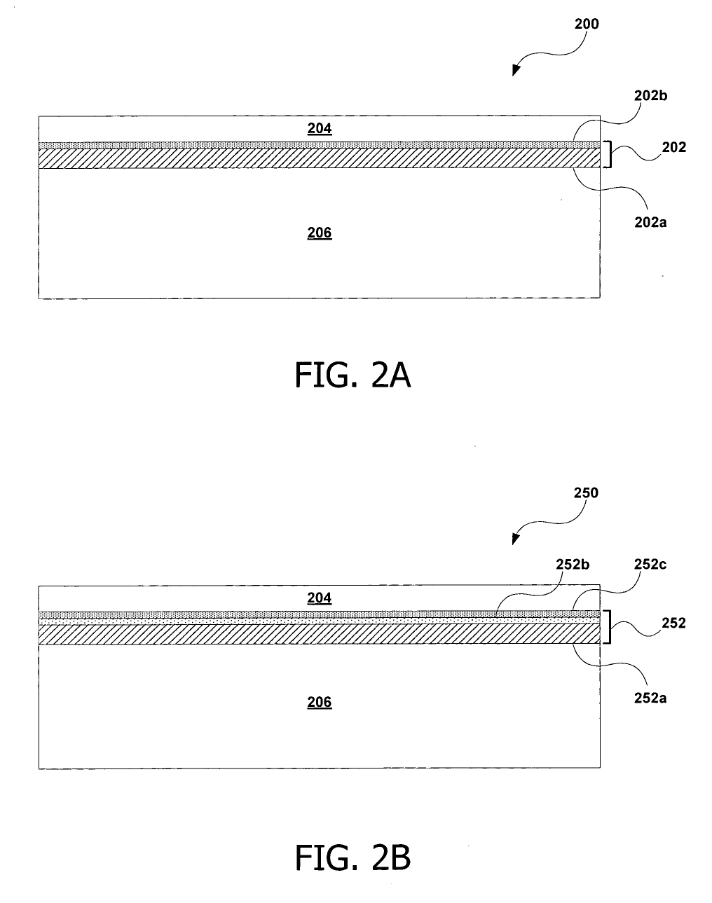

FIG. 2A illustrates an SOI wafer 200 formed in accordance with one implementation of the invention. The SOI wafer 200 includes a dual-insulation layer 202 that consists of a primary insulation layer 202a and a capping insulation layer 202b. The dual insulation layer 202 is formed between a thin silicon device layer 204 and a bulk silicon substrate 206.

In some implementations, the primary insulation layer 202a may be a silicon dioxide layer or an N-doped SiO₂ layer. Alternately, the primary insulation layer 202a may be formed from other insulating materials, including but not limited to carbon doped oxide (CDO), N-doped CDO, organic polymers, N-doped organic polymers, perfluorocyclobutane (PFCB), N-doped PFCB, oxynitrides, N-doped oxynitrides, fluorosilicate glass (FSG), or N-doped FSG.

In accordance with implementations of the invention, the capping insulation layer 202b may be a thin protective insulation layer that is located between the primary insulation layer 202a and the thin silicon device layer 204. In some implementations, the capping insulation layer 202b may be formed from SiON. In alternate implementations, the protective insulation layer 208 may be formed from silicon nitride (SiN). In further implementations, the capping insulation layer 202b may contain both SiON and SiN.

As described above, processes may be carried out to form devices, such as transistors, on the thin silicon device layer 204. The device processes may include ion implantation processes, doping processes, photolithography processes, metallization processes, stress inducing processes, and etching processes. During the device processing, the capping insulation layer 202b substantially seals the primary insulation layer 202a and protects it from any device processes that may otherwise damage the primary insulation layer 202a. For instance, the capping insulation layer 202b may function as an etch stop layer to protect the primary insulation layer 202a from any etching processes that are carried out.

FIG. 2B illustrates another implementation of an SOI wafer 250 constructed in accordance with the invention. The SOI wafer 250 in this implementation includes a tri-insulation layer 252 that consists of a primary insulation layer 252a, a first capping insulation layer 252b, and a second capping insulation layer 252c. The tri-insulation layer 252 is formed between a thin silicon device layer 204 and a bulk silicon substrate 206.

The primary insulation layer 252a may be a silicon dioxide layer. Alternately, the primary insulation layer 252a may be formed from other insulating materials as described above. The first capping insulation layer 252b may be a protective insulation layer that is located between the primary insulation layer 252a and the second capping insulation layer 252c. In some implementations, the first capping insulation layer 252b may consist of an N-doped SiO₂ layer. The second capping insulation layer 252c may be a protective insulation layer that is located between the first insulation layer 252b and the thin silicon device layer 204. In some implementations, the second capping insulation layer 252b may be formed from SiON and/or SiN.

During device processing on the thin silicon device layer 204, the first and second capping insulation layers 252b/c substantially seal the primary insulation layer 252a and protect it from any damaging device processes. For example, the first and second capping insulation layers 252b/c may function as an etch stop layer to protect the primary insulation layer 252a from any etching processes.

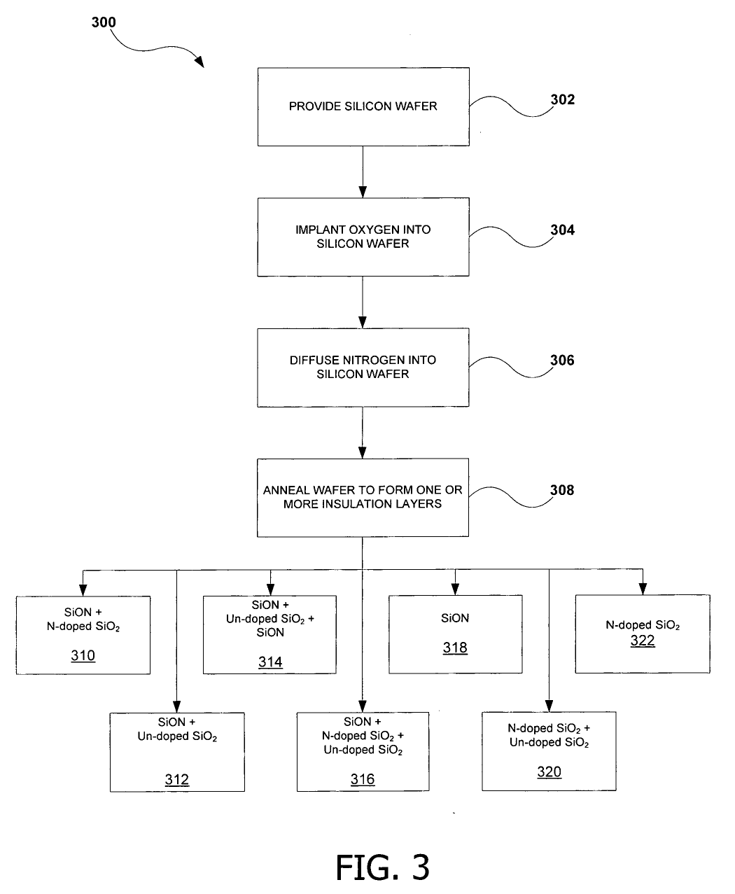

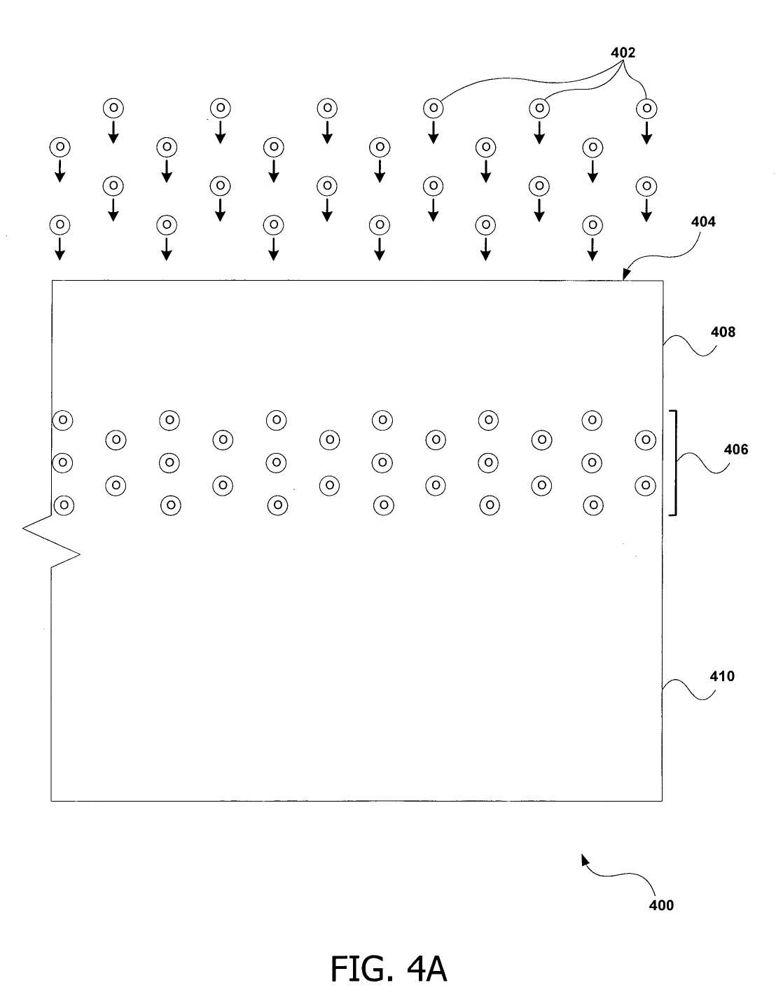

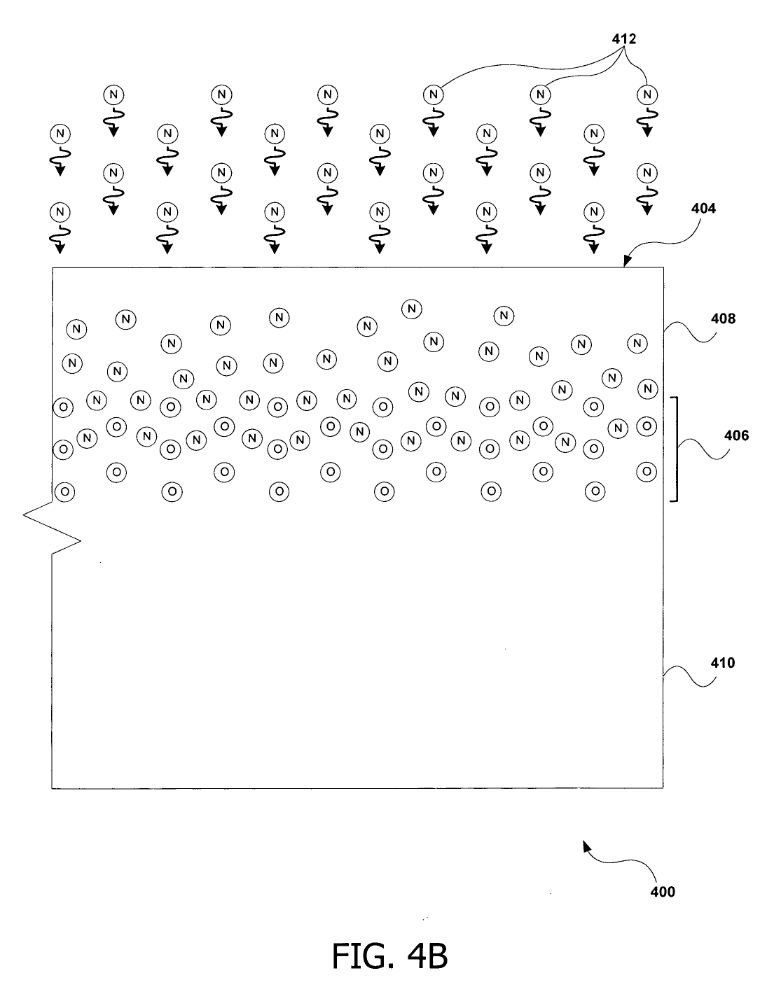

FIG. 3 is a process 300 for forming an SOI wafer in accordance with one implementation of the invention. For clarity, FIGS. 4 through 11 graphically illustrate the steps of process 300. Therefore, the following description of various implementations of the invention will simultaneously refer to both FIG. 3 and FIGS. 4 through 11.

Starting with FIG. 3, the process 300 for forming an SOI wafer in accordance with one implementation of the invention begins by providing a silicon substrate, such as a conventional silicon wafer (302). The silicon wafer may be any type of silicon wafer, such as an epitaxial wafer or a polished wafer, and may be of any size, including but not limited to silicon wafers with diameters of 300 mm or larger.

The silicon wafer undergoes an ion implantation process to implant oxygen ions into the silicon (304). The oxygen ions are generally implanted through a top surface of the silicon wafer and come to rest within the wafer, thereby forming an oxygen layer that is buried within the silicon. The implanted oxygen concentration is a function of wafer depth as well as the oxygen dose and ion energy that is used. In some implementations, the oxygen dose and ion energy used are sufficient to drive the oxygen ions deep into the silicon wafer such that a thin silicon device layer remains at the top surface of the wafer that is substantially oxygen free. A bulk layer of silicon remains below the layer of implanted oxygen.

In one implementation of the invention, the ion implantation process may use an ion energy that ranges from 10 keV to 500 keV and a maximum oxygen dose of around 3.0×10¹⁸ cm⁻². This process may embed the oxygen ions into the wafer at depths that range from 5 nm to 300 nm as measured from the top surface of the silicon wafer. The concentration profile of the oxygen layer may be bell-shaped, with the middle portion of the layer having the highest concentration of ions and the top and bottom portions of the layer having the lowest concentration of ions.

In implementations of the invention, the process parameters, such as the ion energy and dose, may be configured to create oxygen layers of predetermined thicknesses. For instance, the process parameters may be varied to create oxygen layers with thicknesses that range from 20 nm to 200 nm. In some implementations of the invention, process parameters from conventional SIMOX processes may be used to form the embedded oxygen layer.

Turning to FIG. 4A, a silicon wafer 400 is shown undergoing an ion implantation process to implant oxygen 402 into the silicon. The oxygen 402 is implanted through a top surface 404 of the silicon wafer 400 and comes to rest within the wafer, thereby forming an oxygen layer 406 that is buried within the silicon. A thin silicon device layer 408 remains at the top surface 404 of the silicon wafer 400 that may be substantially free of oxygen. A bulk layer of silicon 410 remains below the oxygen layer 406.

Returning to FIG. 3, the silicon wafer undergoes a nitrogen diffusion process to embed nitrogen into the silicon (306). The nitrogen diffuses into the silicon primarily through a top surface of the silicon wafer and generally comes to rest within the thin silicon device layer and the oxygen layer. In accordance with the invention, a diffusion method is used to embed nitrogen within the silicon wafer rather than an ion implantation process because the diffusion process generally provides a more efficient method for embedding nitrogen.

In one implementation of the invention, the nitrogen is diffused into the silicon wafer (i.e., the thin silicon device layer and/or the oxygen layer) by annealing the silicon wafer while exposing the wafer to a flowing nitrogen gas (N₂). The annealing process may be performed at a temperature between 800° C. and 1350° C. for a duration of time that ranges from 10 minutes to 5 hours. For instance, in one implementation, the silicon wafer may be exposed to a flowing nitrogen gas while annealed at a temperature of 1200° C. for 1 to 2 hours. The duration of time needed for a sufficient amount of nitrogen to diffuse into the silicon wafer may vary based on factors that include, but are not limited to, the annealing temperature and the desired nitrogen concentration.

Turning to FIG. 4B, the silicon wafer 400 is shown undergoing a nitrogen diffusion process to embed nitrogen 412 into the silicon wafer 400. Heat from the annealing process drives the nitrogen diffusion. The heat causes the nitrogen 412 to diffuse into the silicon substantially through the top surface 404 of the silicon wafer 400. The nitrogen 412 tends to come to rest within the thin silicon device layer 408 and the oxygen layer 406.

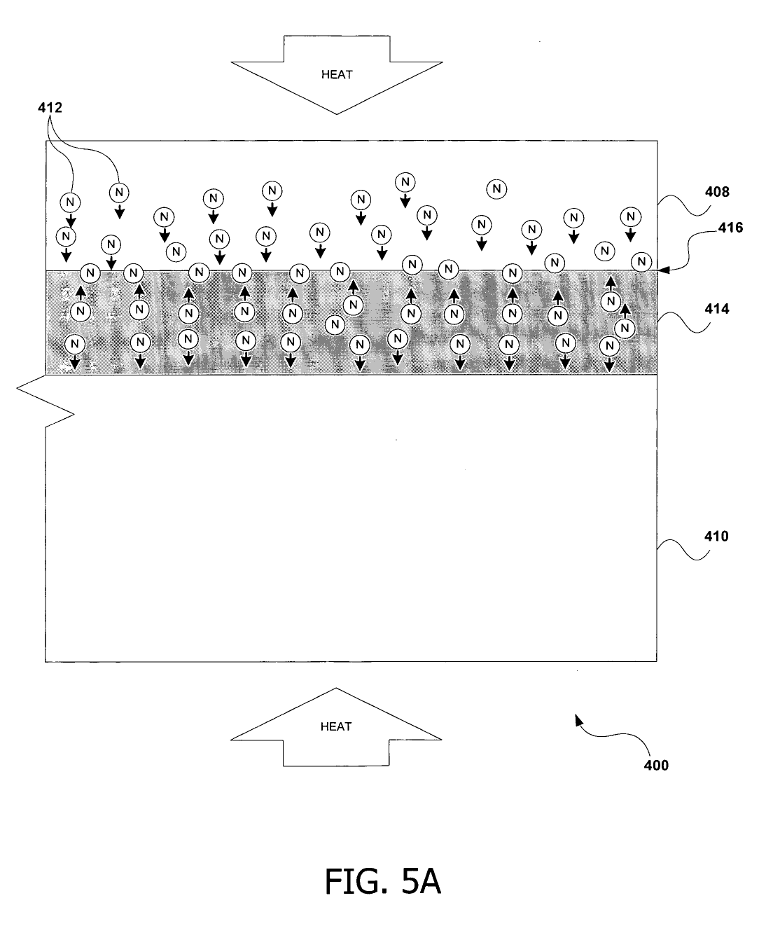

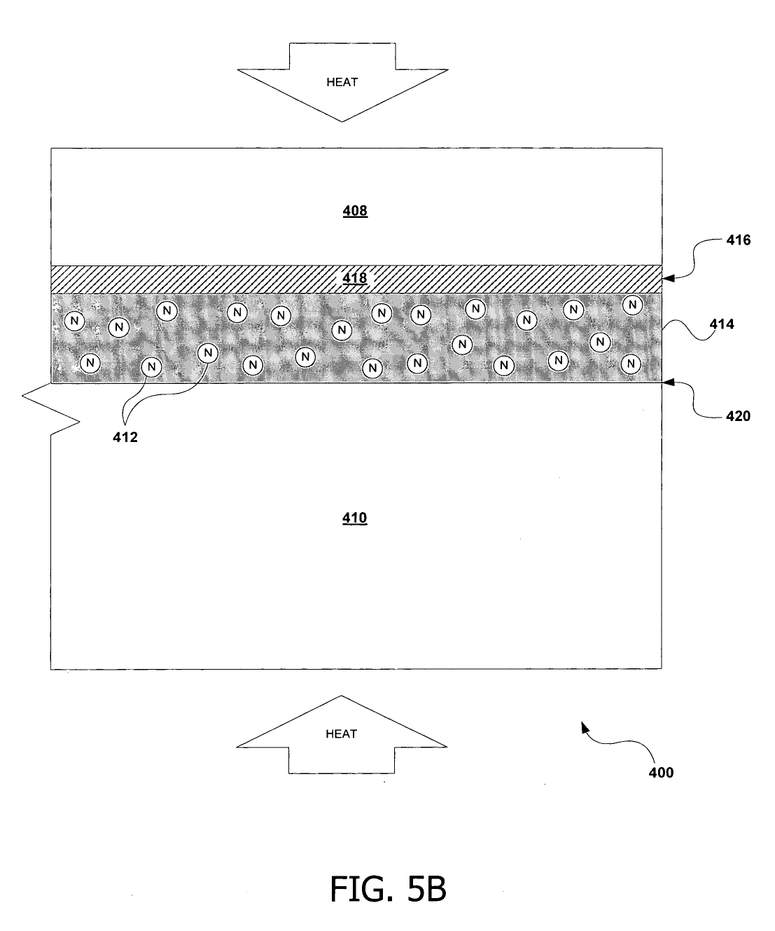

Returning to FIG. 3, the silicon wafer then undergoes a second annealing process at a higher temperature to form one or more insulation layers (308). These are the insulation layers that create the SOI structure. The process parameters chosen for the second annealing process determine what combination of capping insulation layers and primary insulation layers will be formed. Some of the process parameters include, but are not limited to, annealing temperature, annealing time, oxygen concentration within the wafer, oxygen penetration depth within the wafer, nitrogen concentration within the wafer, nitrogen penetration depth within the wafer, and ambient conditions during the anneal. Single or multiple insulation layers that include capping insulation layers formed from SiON, SiN, and/or N-doped SiO₂ may be formed by selecting the appropriate process parameters. FIGS. 5 through 11 illustrate some of the implementations of insulation layers that may be formed. It should be noted that combinations not shown in FIGS. 5 through 11 are possible as well.

FIGS. 5A to 5B illustrate one implementation where the second annealing process (308) may form a primary insulation layer of N-doped SiO₂ and a capping insulation layer of SiON (310). The process parameters for this implementation may be set to anneal the wafer at a temperature around 1350° C. to 1400° C. for 1 to 15 hours in an inert or oxidizing ambient. For example, in one implementation, the wafer may be annealed at a temperature of 1350° C. for 5 to 12 hours. As shown in FIG. 5A, the heat from the annealing process causes the implanted oxygen to react with the silicon to form a silicon dioxide layer 414. The heat also causes the nitrogen 412 to migrate toward the closest Si/SiO₂ interface. One such interface 416 exists between the newly formed silicon dioxide layer 414 and the thin silicon device layer 408.

Turning to FIG. 5B, the heat from the annealing process further causes the nitrogen 412 at the Si/SiO₂ interface 416 to react with the silicon and oxygen to form a SiON capping insulation layer 418. The SiON capping insulation layer 418 may generally have a thickness that ranges from 1 nm to 10 nm, but may generally be less than 5 nm. The SiON capping insulation layer 418 may also have a stoichiometric ratio of Si:O:N that may be very close to 1:1:1.

A portion of the nitrogen 412 remains dispersed throughout the silicon dioxide layer 414, thereby doping the silicon dioxide layer 414 and forming the primary insulation layer of N-doped SiO₂. Some of the nitrogen 412 remains in the silicon dioxide layer 414 because the annealing process ceases before the nitrogen 412 can reach the Si/SiO₂ interface 416. Similarly, some of the nitrogen 412 remains in the silicon dioxide layer 414 because it was migrating towards an Si/SiO₂ interface 420 between the silicon dioxide layer 414 and the bulk silicon layer 410, and the annealing process ceases before the nitrogen 412 can reach that Si/SiO₂ interface 420.

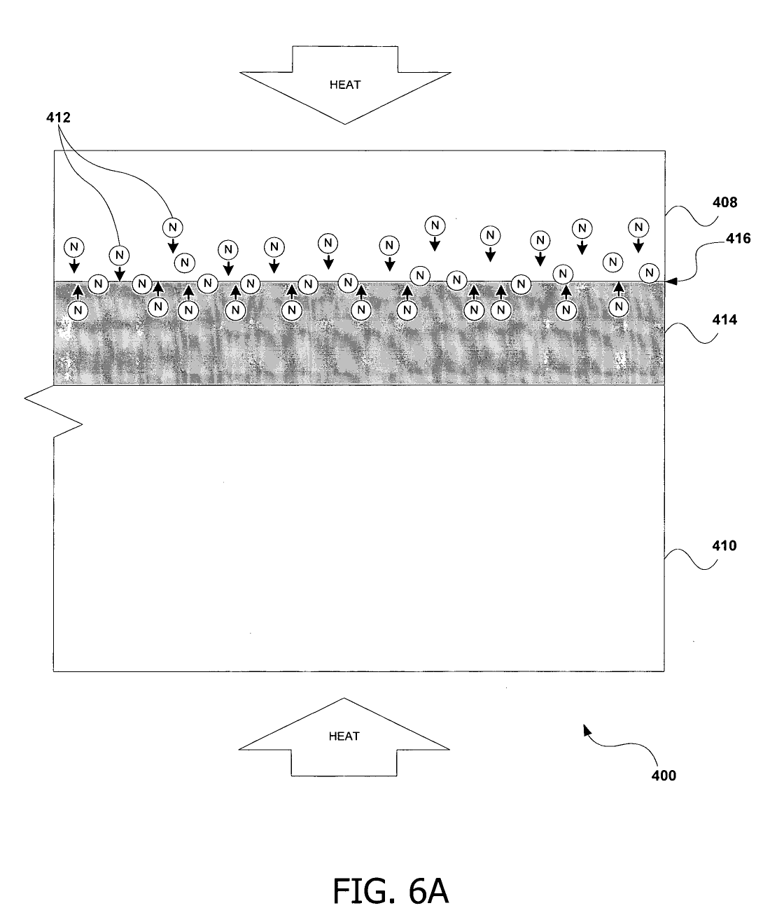

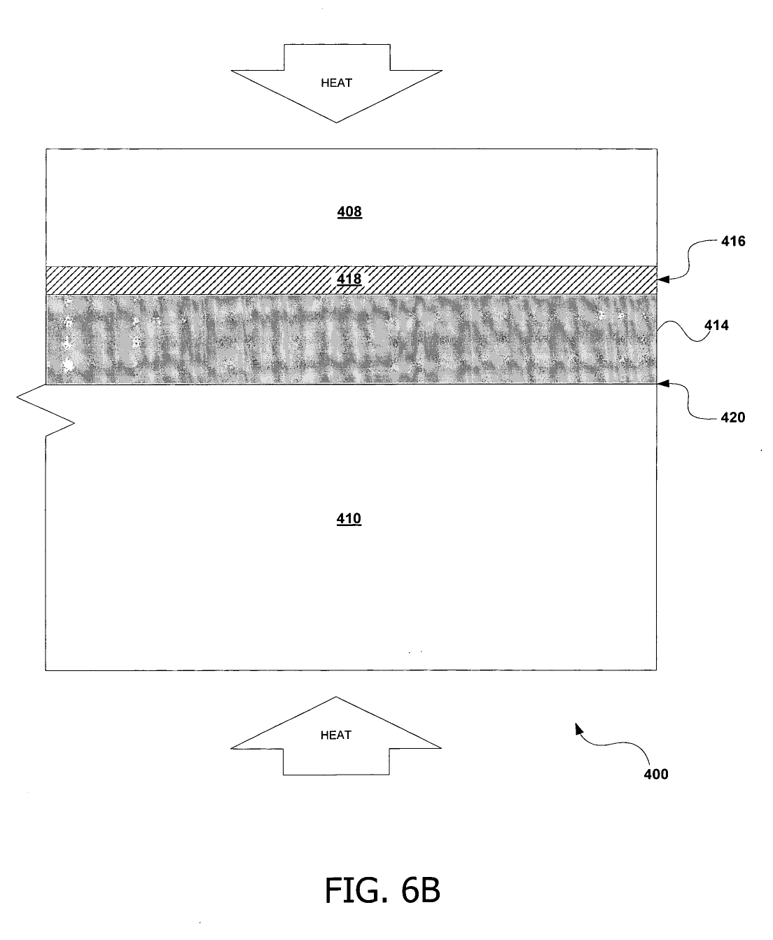

FIGS. 6A to 6B illustrate another implementation of the invention where the second annealing process (308) may form a primary insulation layer of substantially un-doped SiO₂ and a capping insulation layer of SiON (312). The process parameters for this implementation may be set to anneal the wafer 400 at a temperature around 1350° C. to 1400° C. under an inert or oxidizing ambient. As shown in FIG. 6A, this causes the implanted oxygen to react with the silicon to form the silicon dioxide layer 414 and causes the diffused nitrogen 412 to migrate toward the Si/SiO₂ interface 416 between the silicon dioxide layer 414 and the thin silicon device layer 408. This is similar to what was shown in FIG. 5A above.

Turning to FIG. 6B, however, in this implementation the annealing process may be carried out for a duration of time that is sufficient to allow substantially all of the diffused nitrogen 412 to migrate out of the silicon dioxide layer 414 and react to form the SiON capping insulation layer 418 at the interface 416. This results in a primary insulation layer of silicon dioxide 414 that is substantially nitrogen-free.

In some implementations, the nitrogen diffusion process (306) described above may be configured to cause the diffused nitrogen 412 to remain close to the Si/SiO₂ interface 416 where the capping insulation layer 418 will be formed, as shown in FIG. 6A. In other words, the diffusion process may be adjusted so the diffused nitrogen 412 does not deeply penetrate the oxygen layer 406. This causes substantially all of the nitrogen 412 to migrate to the Si/SiO₂ interface 416 between the silicon dioxide layer 414 and the thin silicon device layer 408 rather than the Si/SiO₂ interface 420 between the silicon dioxide layer 414 and the bulk silicon layer 410. Confining the diffused nitrogen 412 to an area along the Si/SiO₂ interface 416 therefore assists in forming the undoped SiO₂ layer.

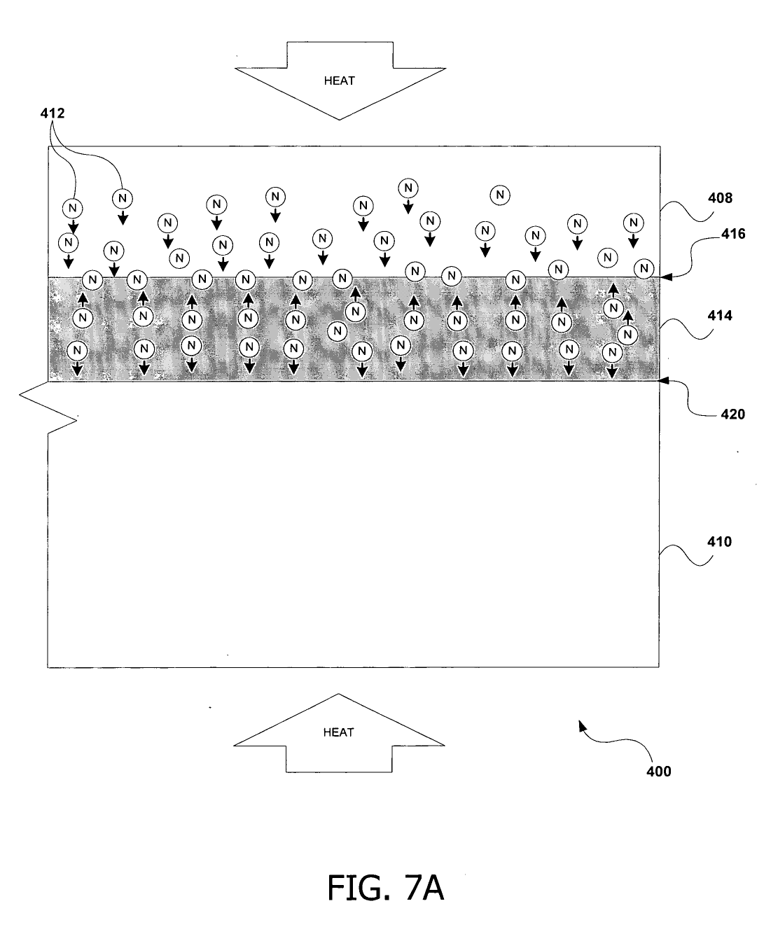

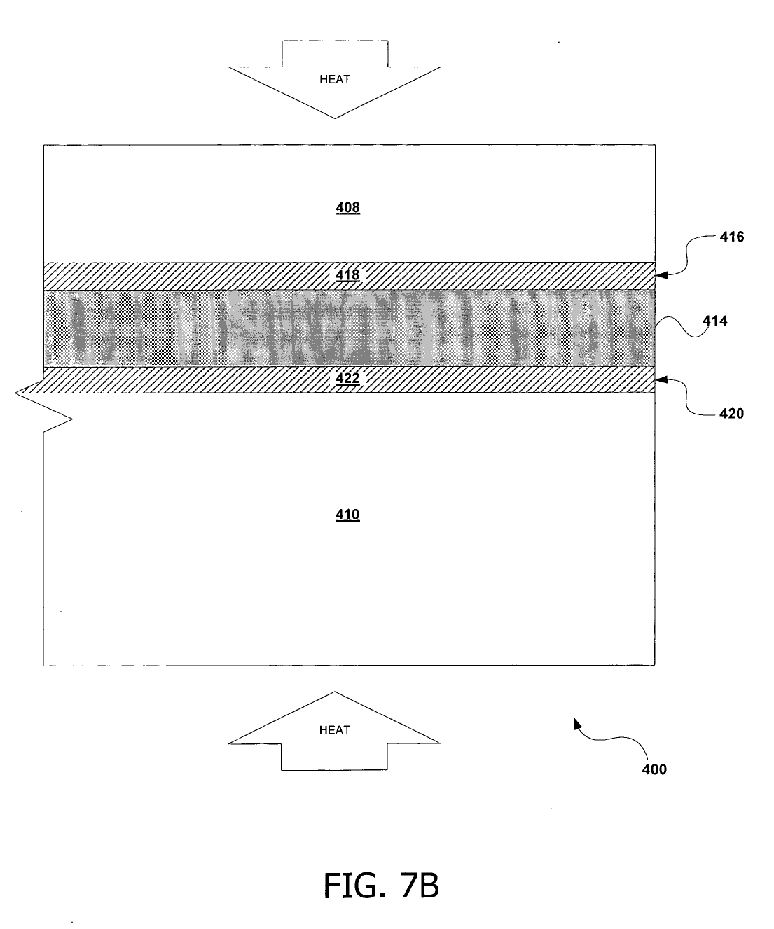

FIGS. 7A and 7B illustrate a variation of the implementation of FIG. 6 in which the nitrogen 412 may be allowed to migrate to both Si/SiO₂ interfaces 416 and 420, thereby forming two SiON capping insulation layers (314). FIG. 7A illustrates how the annealing process causes the nitrogen 412 to migrate towards both Si/SiO₂ interfaces 416 and 420. FIG. 7B illustrates the formation of two SiON capping insulation layers. The first layer is still the SiON capping insulation layer 418. The second layer is a SiON capping insulation layer 422 that is formed between the silicon dioxide layer 414 and the bulk silicon layer 410. This results in a tri-insulation layer that consists of an un-doped SiO₂ primary insulation layer 414 sandwiched between two SiON capping insulation layers 418 and 422. In an alternate implementation, the nitrogen may not completely migrate out of the silicon dioxide layer, resulting in a tri-insulation layer that consists of an N-doped SiO₂ primary insulation layer 414 sandwiched between two SiON capping insulation layers 418 and 422.

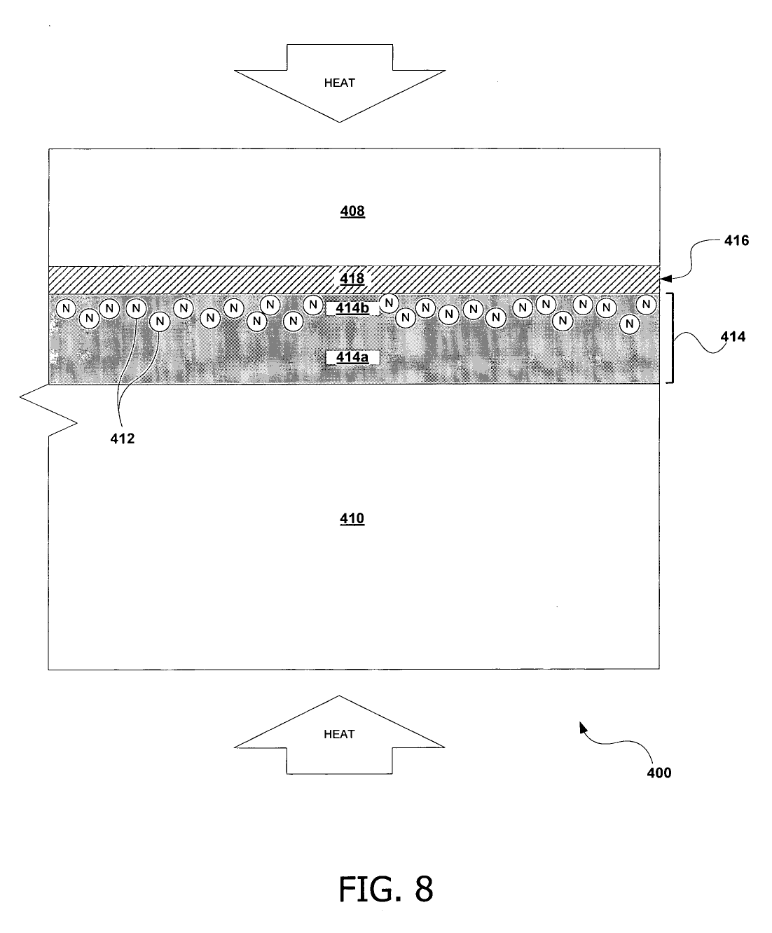

FIG. 8 illustrates another variation of the implementation of FIG. 6 in which the second annealing process (308) may be carried out for a duration of time that is sufficient to allow substantially all of the diffused nitrogen 412 to migrate out of just a portion 414a of the silicon dioxide layer 414, thereby forming a tri-insulation layer (316). The un-doped portion 414a of the silicon dioxide layer 414 becomes the primary insulation layer. A portion 414b of the silicon dioxide layer 414 that still contains nitrogen 412 becomes an N-doped SiO₂ capping insulation layer. The tri-insulation layer therefore consists of an un-doped SiO₂ primary insulation layer 414a with two capping insulation layers, one formed of N-doped SiO₂ 414b and one formed of SiON 418.

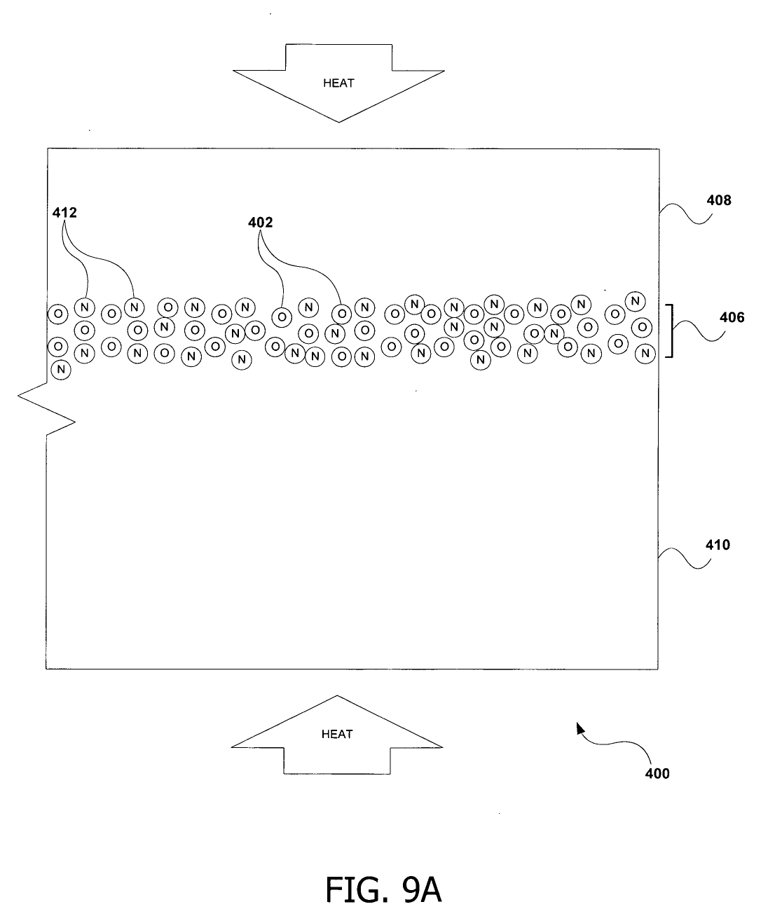

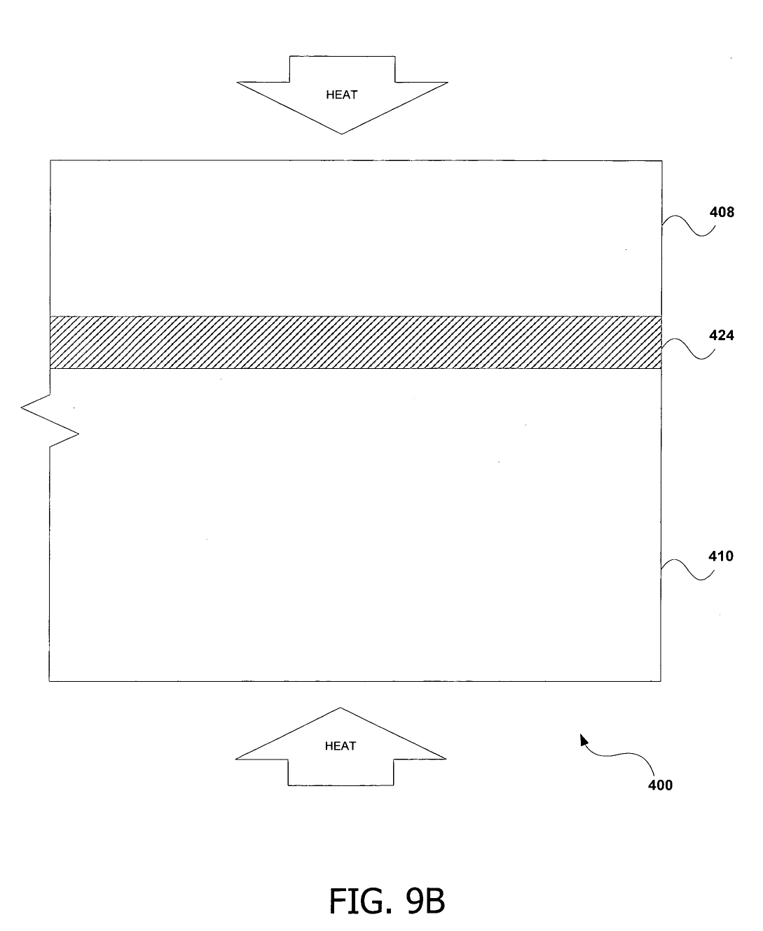

FIGS. 9A and 9B illustrate yet another implementation of the invention in which the second annealing process (308) may form a single insulation layer of SiON (318). As shown in FIG. 9A, the oxygen implantation process (304) described above may be configured to implant a relatively thin layer of oxygen 406. In one implementation, the thickness of this oxygen layer 406 may range from 50 Angstroms (Å) to 1000 Å. The process parameters may be set to anneal the wafer 400 at a temperature around 1350° C. to 1400° C. under an inert or oxidizing ambient. And as shown in FIG. 9B, under the appropriate process conditions, the diffused nitrogen 412 may react with the oxygen 402 and the silicon to form a SiON layer 424 that functions as the sole insulating layer for the SOI wafer.

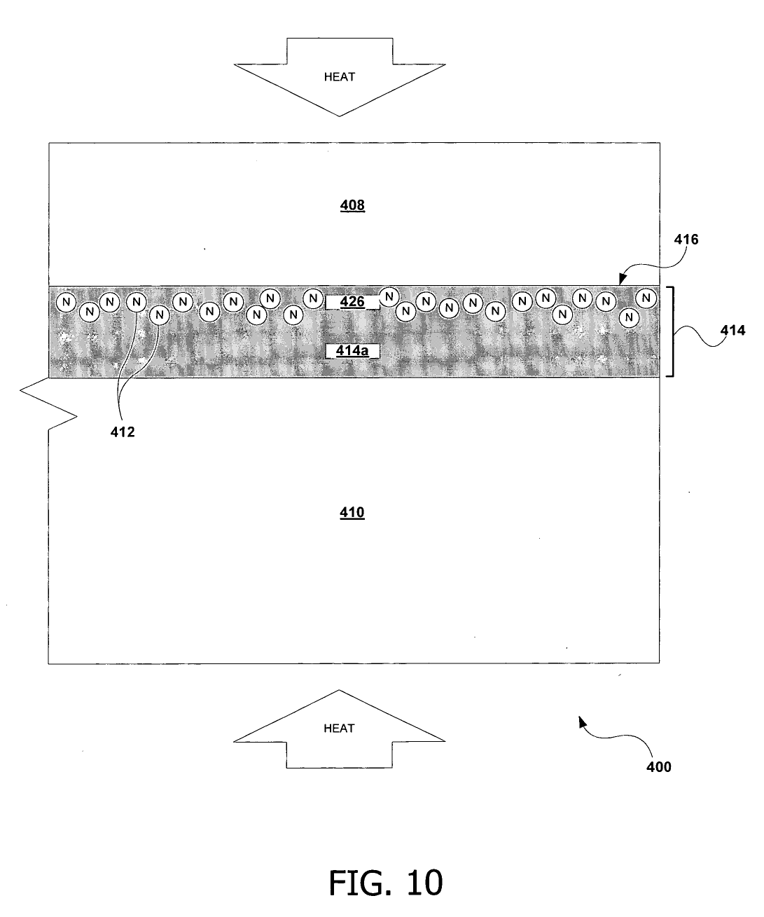

FIG. 10 illustrates an alternate implementation of the invention in which the second annealing process (308) may form a primary insulation layer of substantially un-doped SiO₂ and a capping insulation layer of N-doped SiO₂ (320). The process parameters for this implementation may be set to anneal the wafer 400 under an inert or oxidizing ambient at a temperature around 1350° C., for instance, at a temperature between 1300° C. and 1400° C. The heat causes the implanted oxygen to react with the silicon to form a silicon dioxide layer 414 and causes the diffused nitrogen 412 to migrate toward the Si/SiO₂ interface 416 between the silicon dioxide layer 414 and the thin silicon device layer 408. Under the appropriate conditions, however, the nitrogen 412 will not react to form silicon oxynitride. Instead, the nitrogen 412 remains embedded at or near the Si/SiO₂ interface 416 and forms a capping insulation layer of N-doped SiO₂ 426. The second annealing process (308) may be carried out for a duration of time that is sufficient to allow substantially all of the diffused nitrogen 412 to migrate out of at least a portion 414a of the silicon dioxide layer 414, and this portion 414a becomes un-doped SiO₂ primary insulation layer.

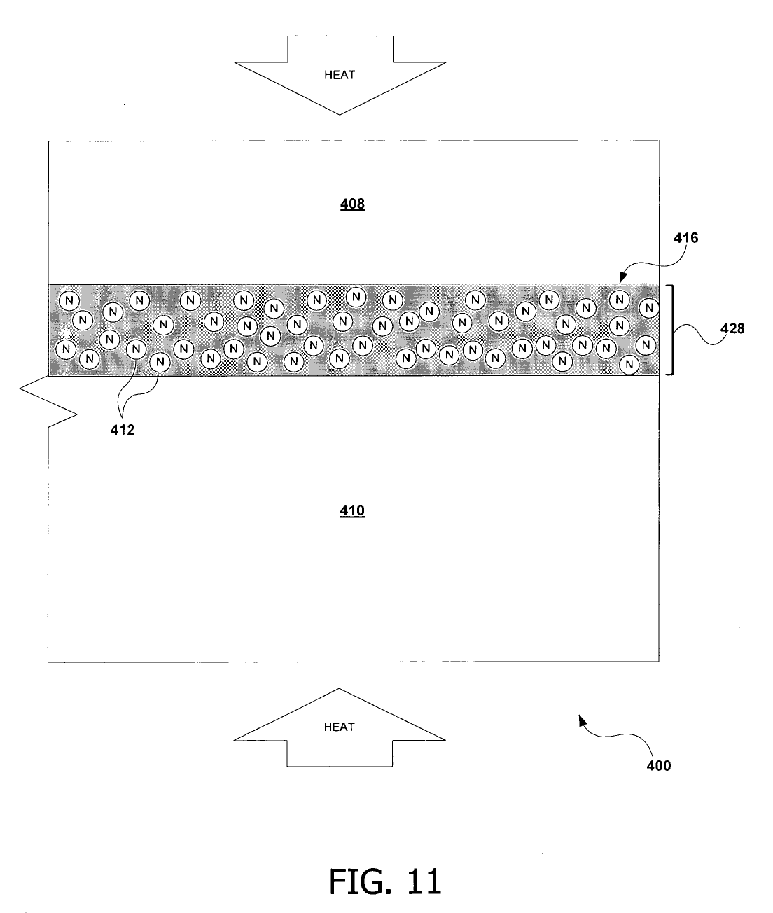

FIG. 11 illustrates another implementation of the invention in which the second annealing process (308) may form a single insulation layer of N-doped SiO₂ (322). The process parameters for this implementation may be set to anneal the wafer 400 under an inert or oxidizing ambient at a temperature near 1350° C., for instance, at a temperature between 1300° C. and 1350° C. The lowered heat still causes the implanted oxygen 402 to react with the silicon to form a silicon dioxide layer without forming silicon oxynitride. The second annealing process (308) may be carried out for a duration of time that is sufficient to form the silicon dioxide layer 414 but is insufficient to cause the diffused nitrogen 412 to completely migrate out of the silicon dioxide layer. In other words, the second annealing process (308) may be halted while nitrogen 412 is still dispersed throughout the silicon dioxide layer. The result is an N-doped SiO₂ layer 428 that functions as the sole insulating layer for the SOI wafer 400.

In alternate implementations of the invention, a SiN layer may be formed either in addition to the SiON layer or in place of the SiON layer in any of the above described implementations that include a SiON capping insulation layer.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An SOI wafer comprising:
a silicon device layer;
a bulk silicon layer; and
a multi-insulation layer disposed between the silicon device layer and the bulk silicon layer.

2. The SOI wafer of claim 1, wherein the multi-insulation layer comprises a first insulation layer and a second insulation layer, wherein the first insulation layer is disposed between the bulk silicon layer and the second insulation layer.

3. The SOI wafer of claim 2, wherein the first insulation layer comprises a nitrogen-doped silicon dioxide layer and the second insulation layer comprises a silicon oxynitride layer.

4. The SOI wafer of claim 2, wherein the first insulation layer comprises an un-doped silicon dioxide layer and the second insulation layer comprises a silicon oxynitride layer.

5. The SOI wafer of claim 2, wherein the first insulation layer comprises an un-doped silicon dioxide layer and the second insulation layer comprises a nitrogen-doped silicon dioxide layer.

6. The SOI wafer of claim 1, wherein the multi-insulation layer comprises a first insulation layer, a second insulation layer, and a third insulation layer, wherein the first insulation layer is disposed between the bulk silicon layer and the second insulation layer and wherein the second insulation layer is disposed between the first insulation layer and the third insulation layer.

7. The SOI wafer of claim 6, wherein the first insulation layer comprises a silicon oxynitride layer, the second insulation layer comprises an undoped silicon dioxide layer, and the third insulation layer comprises a silicon oxynitride layer.

8. The SOI wafer of claim 6, wherein the first insulation layer comprises a silicon oxynitride layer, the second insulation layer comprises a nitrogen-doped silicon dioxide layer, and the third insulation layer comprises a silicon oxynitride layer.

9. The SOI wafer of claim 6, wherein the first insulation layer comprises an un-doped silicon dioxide layer, the second insulation layer comprises a nitrogen-doped silicon dioxide layer, and the third insulation layer comprises a silicon oxynitride layer.

10. An SOI wafer comprising:
a silicon device layer;
a bulk silicon layer; and
a silicon oxynitride layer disposed between the silicon device layer and the bulk silicon layer.

11. The SOI wafer of claim 10, wherein the nitrogen used to form the silicon oxynitride layer was deposited in the SOI wafer using a diffusion process.

12. An SOI wafer comprising:
a silicon device layer;
a bulk silicon layer; and
a nitrogen-doped silicon dioxide layer disposed between the silicon device layer and the bulk silicon layer.

13. The SOI wafer of claim 12, wherein the nitrogen used to dope the nitrogen-doped silicon dioxide layer was deposited in the SOI wafer using a diffusion process.

14. A method comprising:
providing a silicon wafer having a first surface;
implanting oxygen within the silicon wafer to form an oxygen layer that is buried within the silicon wafer;
diffusing nitrogen into the silicon wafer; and
annealing the silicon wafer to form a silicon dioxide layer and a silicon oxynitride layer, wherein the annealing process causes the implanted oxygen to react with the silicon to form the silicon dioxide layer and causes the diffused nitrogen to migrate and react with the silicon and the implanted oxygen to form the silicon oxynitride layer.

15. The method of claim 14, wherein the implanting of the oxygen comprises using an ion implantation process to implant oxygen within the silicon wafer.

16. The method of claim 15, wherein the ion implantation process uses an ion energy that is greater than or equal to 10 keV and less than or equal to 500 keV.

17. The method of claim 15, wherein the ion implantation process uses an oxygen dose that is less than or equal to 3.0×10¹⁸ cm⁻².

18. The method of claim 14, wherein the diffusing of the nitrogen comprises annealing the silicon wafer under a nitrogen ambient.

19. The method of claim 18, wherein the annealing of the silicon wafer under a nitrogen ambient comprises annealing the silicon wafer at a temperature that is greater than or equal to 800° C. and less than 1350° C. for a duration of time between 10 minutes and 5 hours while flowing a nitrogen gas across the first surface of the silicon wafer.

20. The method of claim 18, wherein the annealing of the silicon wafer under a nitrogen ambient comprises annealing the silicon wafer at a temperature around 1200° C. for a duration of time between 1 and 2 hours while flowing a nitrogen gas across the first surface of the silicon wafer.

21. The method of claim 14, wherein the annealing of the silicon wafer to form the silicon dioxide layer and the silicon oxynitride layer comprises annealing the silicon wafer at a temperature that is greater than or equal to 1350° C. and less than or equal to 1400° C. for a duration of time between 1 and 15 hours under an oxidizing or inert ambient.

22. The method of claim 14, wherein the annealing of the silicon wafer to form the silicon dioxide layer and the silicon oxynitride layer comprises annealing the silicon wafer at a temperature around 1350° C. for a duration of time between 5 and 12 hours under an inert or oxidizing ambient.

23. The method of claim 14, wherein a portion of the diffused nitrogen remains within the silicon dioxide layer to form a nitrogen-doped silicon dioxide layer.

24. A method comprising:
providing a silicon wafer having a first surface;
implanting oxygen within the silicon wafer to form an oxygen layer that is buried within the silicon wafer, thereby forming a silicon device layer between the oxygen layer and the first surface that remains substantially free of oxygen;
diffusing nitrogen into the silicon wafer, wherein the nitrogen diffuses into the silicon device layer and the oxygen layer; and
annealing the silicon wafer to form a silicon dioxide layer and a nitrogen-doped silicon dioxide layer, wherein the annealing process causes the implanted oxygen to react with the silicon to form the silicon dioxide layer and causes the diffused nitrogen to migrate and form the nitrogen-doped silicon dioxide layer.

25. The method of claim 24, wherein the implanting of the oxygen comprises using an ion implantation process to implant oxygen within the silicon wafer.

26. The method of claim 25, wherein the ion implantation process uses an ion energy that is greater than or equal to 10 keV and less than or equal to 500 keV, and wherein the ion implantation process uses an oxygen dose that is less than or equal to

27. The method of claim 24, wherein the diffusing of the nitrogen comprises annealing the silicon wafer under a nitrogen ambient.

28. The method of claim 27, wherein the annealing of the silicon wafer under a nitrogen ambient comprises annealing the silicon wafer at a temperature that is greater than or equal to 800° C. and less than 1350° C. for a duration of time between 10 minutes and 5 hours while flowing a nitrogen gas across the first surface of the silicon wafer.

29. The method of claim 24, wherein the annealing of the silicon wafer to form the silicon dioxide layer and the nitrogen-doped silicon dioxide layer comprises annealing the silicon wafer at a temperature that is greater than or equal to 1300° C. and less than 1350° C. for a duration of time between 1 and 15 hours under an oxidizing or inert ambient.

30. A method comprising:
performing an ion implantation process to implant oxygen within a silicon wafer, wherein the implanted oxygen forms an oxygen layer that is buried within the silicon wafer;
performing a first anneal on the silicon wafer under a nitrogen ambient, thereby causing the nitrogen to diffuse into the silicon wafer; and
performing a second anneal on the silicon wafer under an inert or oxidizing ambient, thereby causing the implanted oxygen to react with the silicon to form a silicon dioxide layer and causing the diffused nitrogen to react with the silicon and the implanted oxygen to form a silicon oxynitride layer.

31. The method of claim 30, wherein the ion implantation process uses an ion energy between 10 keV and 500 keV and an oxygen dose of less than or equal to 3.0×10¹⁸ cm⁻².

32. The method of claim 30, wherein the first anneal is carried out at a temperature between 1000° C. and 1350° C. for a duration of time between 10 minutes and 5 hours.

33. The method of claim 30, wherein the second anneal is carried out at a temperature between 1350° C. and 1400° C. for a duration of time between 1 and 15 hours.
